(19) United States
(12) Patent Application Publication
(10) Pub. No.: US 2026/0157096 A1
(43) Pub. Date: Jun. 4, 2026

(54) DISPLAY PANEL AND DISPLAY APPARATUS

(71) Applicant: Hubei Yangtze Industrial Innovation Center Of Advanced Display Co., Ltd., Wuhan (CN)

(72) Inventors: Liang HU, Wuhan (CN); Li XIAO, Wuhan (CN)

(73) Assignee: Hubei Yangtze Industrial Innovation Center Of Advanced Display Co., Ltd., Wuhan (CN)

(21) Appl. No.: 19/393,537

(22) Filed: Nov. 18, 2025

(30) Foreign Application Priority Data
Nov. 29, 2024 (CN) 202411748767.2

(51) Int. Cl. H10K 59/80; H10K 59/122

(52) U.S. Cl. CPC H10K 59/8792; H10K 59/122

(57) ABSTRACT

Embodiments of the present application provide a display panel and a display apparatus, which relates to the field of display technology. The display panel includes a first display area; and the first display area includes a plurality of sub-pixels including a light-emitting element. The display panel includes a substrate and a light-shielding layer located at a side of the substrate, the light-shielding layer includes a plurality of light-transmitting aperture groups located in the first display area and arranged in an array along a first direction and a second direction, the light-transmitting aperture groups each include N light-transmitting apertures arranged along the first direction and having areas different from each other, and in a direction perpendicular to a plane where the display panel is located, the light-transmitting apertures do not overlap with the light-emitting elements.

### CROSS-REFERENCE TO RELATED APPLICATION

The present application claims priority to Chinese Patent Application No 202411748767.2, entitled “DISPLAY PANEL AND DISPLAY APPARATUS”, filed on Nov. 29, 2024, which is incorporated herein by reference in its entirety.

### TECHNICAL FIELD

The present application relates to the field of display technology, and particularly, to a display panel and a display apparatus.

### BACKGROUND

With the continuous development of display technology, there are more and more display devices carrying optical sensors with a photosensitive function. At present, in order to increase the screen-to-body ratio of a display panel, the optical sensor is usually integrated in an area where the display area of the display panel is located. For such design, how to increase the light transmittance of the display panel and increase the light intensity received by the optical sensor has become the research focus of relevant technicians.

### SUMMARY

In view of this, the present application provides a display panel and a display apparatus for increasing the light transmittance of the display panel.

In a first aspect, embodiments of the present application provide a display panel including a first display area; the first display area includes a plurality of sub-pixels including light-emitting elements;
the display panel includes:
a substrate; and
a light-shielding layer located at a side of the substrate, the light-shielding layer includes a plurality of light-transmitting aperture groups located in the first display area, the light-transmitting aperture groups are arranged in an array along a first direction and a second direction, the light-transmitting aperture groups each include N light-transmitting apertures arranged along the first direction and have areas different from each other, and in a direction perpendicular to a plane where the display panel is located, the light-transmitting apertures do not overlap with the light-emitting elements; where N is an integer and N≥2.

In a second aspect, embodiments of the present application provide a display apparatus including an optical sensor and the display panel; an orthographic projection of the optical sensor on the plane where the substrate is located is at least partially located in the first display area.

### BRIEF DESCRIPTION OF THE DRAWINGS

In order to illustrate the technical solutions of the embodiments of the present application more clearly, the drawings to be used in the embodiments will be briefly introduced below. It is obvious that the drawings described below are merely some embodiments of the present application, and for those of ordinary skill in the art, other drawings can be obtained based on these drawings without inventive effort.

FIG. 1 is a schematic diagram of a display panel according to embodiments of the present application;

FIG. 2 is an enlarged schematic diagram of a first display area in FIG. 1;

FIG. 3 is a schematic cross-sectional diagram taken along BB′ in FIG. 2;

FIG. 4 is a diffracted light intensity simulation comparison diagram according to embodiments of the present application;

FIG. 5 is another enlarged schematic diagram of a first display area in FIG. 1;

FIG. 6 is a diagram of diffraction curves under different grating constants according to embodiments of the present application;

FIG. 7 is an enlarged schematic diagram of a second display area in FIG. 1;

FIG. 8 is a schematic wiring diagram of a first display area according to embodiments of the present application;

FIG. 9 is a schematic diagram of a pixel driving circuit corresponding to FIG. 8 according to embodiments of the present application;

FIG. 10 is a simplified schematic diagram of a first signal wire, a second signal wire, a first light-transmitting aperture, and a second light-transmitting aperture according to embodiments of the present application;

FIG. 11 is another simplified schematic diagram of a first signal wire, a second signal wire, a first light-transmitting aperture, and a second light-transmitting aperture according to embodiments of the present application;

FIG. 12 is yet another simplified schematic diagram of a first signal wire, a second signal wire, a first light-transmitting aperture, and a second light-transmitting aperture according to embodiments of the present application;

FIG. 13 is yet another simplified schematic diagram of a first signal wire, a second signal wire, a first light-transmitting aperture, and a second light-transmitting aperture according to embodiments of the present application;

FIG. 14 is yet another simplified schematic diagram of a first signal wire, a second signal wire, a first light-transmitting aperture, and a second light-transmitting aperture according to embodiments of the present application;

FIG. 15 is yet another simplified schematic diagram of a first signal wire, a second signal wire, a first light-transmitting aperture, and a second light-transmitting aperture according to embodiments of the present application;

FIG. 16 is a simplified schematic diagram of a third signal wire, a fourth signal wire, a first light-transmitting aperture, and a second light-transmitting aperture according to embodiments of the present application;

FIG. 17 is another simplified schematic diagram of a third signal wire, a fourth signal wire, a first light-transmitting aperture, and a second light-transmitting aperture according to embodiments of the present application;

FIG. 18 is another schematic cross-sectional diagram taken along BB′ in FIG. 2;

FIG. 19 is a schematic diagram of an optical path along which ambient light passes through a light-transmitting aperture and a light-shielding metal; and

FIG. 20 is a schematic diagram of a display apparatus according to embodiments of the present application.

### DETAILED DESCRIPTION

In order to better understand the technical solution of the present application, embodiments of the present application will be described in detail below with reference to the drawings.

It should be clear that the described embodiments are only some but not all of the embodiments of the present application. Based on the embodiments of the present application, all other embodiments obtained by those of ordinary skill in the art without any creative work fall within the protection scope of the present application.

The terms used in the embodiments of the present application are for the purpose of describing particular embodiments only and are not intended to limit the present application. Unless the context clearly indicates, the singular forms “a”, “said”, and “the” used in the embodiments and the appended claims of the present application are also intended to include plural forms.

It should be understood the term “and/of” used herein refers to only an association relationship for describing associated objects, and means that there may be three kinds of relationships. For example, “A and/or B” may represent three cases including: “A exists alone”, “A and B exist simultaneously”, and “B exists alone”. In addition, the character “/” herein generally indicates that the associated objects have an “of” relationship.

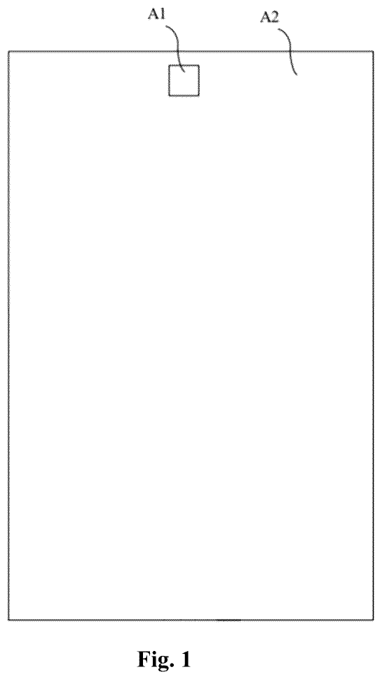

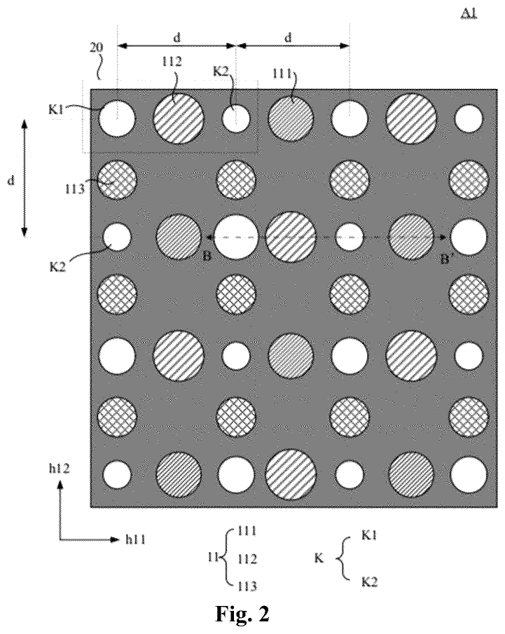

Embodiments of the present application provide a display panel. As shown in FIG. 1, FIG. 1 is a schematic diagram of a display panel according to embodiments of the present application, and the display panel includes the first display area A1. Referring to FIGS. 2 and 3, FIG. 2 is an enlarged schematic diagram of a first display area A1 in FIG. 1, and FIG. 3 is a schematic cross-sectional diagram taken along BB′ in FIG. 2. The first display area A1 includes sub-pixels, and the sub-pixels include the light-emitting elements 11. Exemplarily, the display panel includes light-emitting elements of a plurality of colors; in FIG. 2, it is shown that a plurality of light-emitting elements 11 include first color light-emitting element 111, second color light-emitting element 112, and third color light-emitting element 113. Optionally, the first color light-emitting element 111, the second color light-emitting element 112, and the third color light-emitting element 113 may be red light-emitting element, blue light-emitting element, and green light-emitting element, respectively.

As shown in FIG. 3, the display panel includes a substrate 10 and a light-shielding layer 2 located at a side of the substrate 10, the light-shielding layer 2 includes a plurality of light-transmitting aperture groups 20 arranged in an array along a first direction h11 and a second direction h12, and the light-transmitting aperture group 20 includes N light-transmitting apertures K arranged along the first direction h11 and having areas different from each other, where N is an integer, and N≥2. In the direction perpendicular to the plane where the substrate 10 is located, the light-transmitting aperture K does not overlap with the light-emitting element 11. In other words, on the plane where the substrate 10 is located, the orthographic projection of the light-transmitting aperture K does not overlap with the orthographic projection of the light-emitting element 11. The area of the light-transmitting aperture K refers to the area of the orthographic projection of the light-transmitting aperture K on the plane where the substrate 10 is located. In FIG. 2, it is shown that N=2, that is, the light-transmitting aperture group 20 includes the first light-transmitting aperture K1 and the second light-transmitting aperture K2, and the area of the orthographic projection of the first light-transmitting aperture K1 on the plane where the substrate 10 is located is greater than the area of the orthographic projection of the second light-transmitting aperture K2 on the plane where the substrate 1 is located.

Exemplarily, the first display area A1 includes an area where the optical sensor is disposed. That is, in the embodiments of the present application, the optical sensor may be disposed in the first display area A1, and optionally, the optical sensor may be located at a side of the display panel away from the light-emitting side.

In the embodiments of the present application, the first display area A1 including the light-transmitting aperture group 20 is disposed in the display panel, so that under a condition that the display panel is operating, the ambient light may cast from one side of the display panel to the other side of the display panel where the optical sensor is located through the light-transmitting aperture K in the light-transmitting aperture group 20. The optical sensor may carry out corresponding operations based on the light intensity of the received ambient light. For example, the optical sensor may adjust the brightness of the display panel based on the received light intensity. For example, under a condition that the ambient brightness is relatively strong, the display brightness of the display panel may be increased, so that the user can see the image clearly; under a condition that the ambient brightness is relatively weak, the display brightness of the display panel may be reduced, reducing the power consumption.

In the process in which the ambient light passes through the film layers in the display panel, in addition to the transmission phenomenon that the light transmits through the light-transmitting aperture K, the diffraction phenomenon that the light propagates bypassing the edge of the light-transmitting aperture occurs. A plurality of light-transmitting apertures having the same shape and the same area in different light-transmitting aperture groups 20 may be used as a grating. In FIG. 3, it is shown that L1 is the diffracted light which propagates bypassing the edge of the light-transmitting aperture K. According to the grating equation:

$$L sin θ = k λ \qquad ( 1 )$$

L is the distance between adjacent two of the light-transmitting apertures K having the same shape and the same area, and may be understood as the grating constant; θ is the diffraction angle of the light; k is the diffraction order with the values of 0, ±1, ±2, . . . ; and λ is the wavelength of the light. In the embodiments of the present application, the areas of the plurality of light-transmitting apertures K in the same light-transmitting aperture group 20 are different from each other. Compared to disposing the plurality of light-transmitting apertures having the same area in the light-transmitting aperture group 20, under a condition that the distance between adjacent two of the light-transmitting apertures K is the same and equal to d, the distance between the light-transmitting apertures having the same shape and the same area in adjacent two of the light-transmitting aperture groups 20 may be increased to Nd; for example, under a condition that N=2, that is, the light-transmitting aperture group 20 includes the first light-transmitting aperture K1 and the second light-transmitting aperture K2 having areas different from each other, the distance between adjacent two of the first light-transmitting apertures K1 may be increased to 2d, and the distance between adjacent two of the second light-transmitting apertures K2 may be increased to 2d; that is, the grating constant L in the formula (1) is increased, and under a condition that the diffraction order k and the wavelength λ are constant, the diffraction angle of the light diffracted at the edge of the light-transmitting aperture may be reduced. Under a condition that the diffraction angle is too large, the diffracted light will be absorbed by the light-shielding structure located outside the light-transmitting area located in the film layers and cannot be casted to the optical sensor. The light-transmitting area refers to an area that includes a light-transmitting aperture or a material with high transmittance. The light-transmitting area may be located between adjacent two of the light-emitting elements. Therefore, based on the arrangement according to the embodiments of the present application, the diffraction angle of the diffracted light may be reduced, so that the possibility that the diffracted light enter the optical sensor passing through the first display area A1 of the display panel may be increased, the light transmittance of the first display area A1 may be increased, the intensity of the light entering the optical sensor may be increased, and the operation performance of the optical sensor may be improved.

In the embodiments of the present application, the distance between adjacent two of the light-transmitting apertures K refers to the distance between the centers of adjacent two of the light-transmitting apertures K. Under a condition that the geometric shape of the light-transmitting aperture K is a regular geometric shape, the center of the light-transmitting aperture K coincides with the geometric center of the light-transmitting aperture K; for example, the shape of the light-transmitting aperture K is a parallelogram, and the intersection point of two diagonal lines of the parallelogram is the geometric center of the parallelogram. Under a condition that the geometric shape of the light-transmitting aperture K is an asymmetric irregular geometric shape, the center of the light-transmitting aperture K may be determined by the related art.

The regular pattern (regular geometric shape) in the embodiments of the present application may be a centrosymmetric pattern or an axisymmetric pattern having two or more axes of symmetry. For example, ellipses, parallelograms (non-rectangles and non-diamonds), circles, rounded rectangles, regular polygons, rectangles, diamonds, and the like are all regular patterns. For a centrosymmetric pattern, the centrosymmetric point of the centrosymmetric pattern is the center; for an axisymmetric pattern having two or more axes of symmetry, the intersection point of two axes of symmetry of the axisymmetric pattern is the center. Patterns other than regular patterns are irregular patterns.

In some embodiments, the geometric centers of the light-transmitting apertures K arranged along the first direction are located on a straight line, and/or the geometric centers of the light-transmitting apertures K arranged along the second direction are located on a straight line.

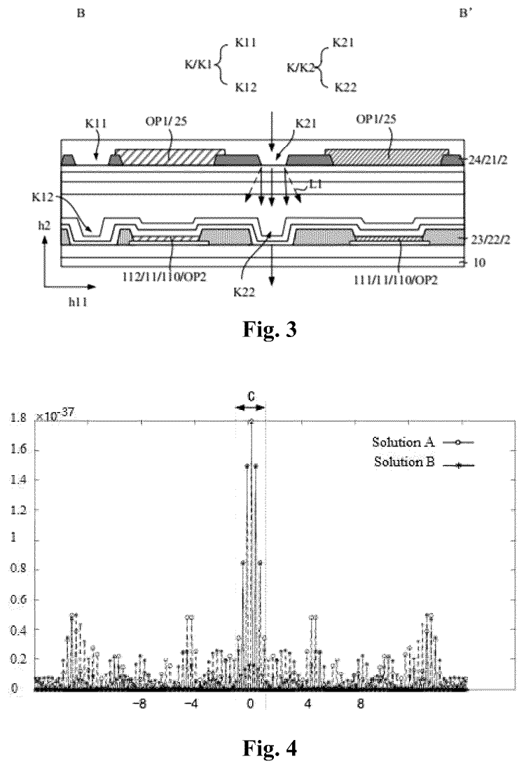

Referring to FIG. 4, which is a diffracted light intensity simulation comparison diagram according to embodiments of the present application; the abscissa is the diffraction order, and the ordinate is the light intensity; the solution A shows that the first display area A1 includes the first light-transmitting aperture with the diameter of 12 m and the second light-transmitting aperture with the diameter of 12.1 m, and the first light-transmitting aperture and the second light-transmitting aperture are alternately arranged; the solution B shows that the first display area A1 includes only the first light-transmitting aperture with the diameter of 12 m; the total number of the light-transmitting apertures in the solution A is equal to the total number of the light-transmitting apertures in the solution B, and the distances between adjacent two of the light-transmitting apertures in the solution A and the solution B are the equal to each other. Based on the simulation results, it may be seen that the intensity contrast of the central area C in the two solutions satisfies: (A−B)/B=5.04%, where A represents the intensity of the central area of the solution A, B represents the intensity of the central area of the solution B, and the central area refers to an area having the diffraction angle ranging from −5° to 5°.

Considering that the sum of the areas of the light-transmitting apertures in the solution A is relatively great, the following is satisfied:

$$\frac{{S}_{A} - {S}_{B}}{{S}_{B}} = \frac{12 . {1}^{2} - {12}^{2}}{1 {2}^{2}} = 1.67 \%$$

where S_{A} represents the sum of the areas of the light-transmitting apertures of the solution A, and S_{B} represents the sum of the areas of the light-transmitting apertures of the solution B. Therefore, taking the factor of area into account, it may be seen that, compared to the solution B, the solution A achieves the transmittance improvement satisfying 5.04%−1.67%=3.37%; that is, in the embodiments of the present application, the areas of the plurality of light-transmitting apertures in the same light-transmitting aperture group 20 are different from each other, so that the transmittance of the first display area A1 may be increased.

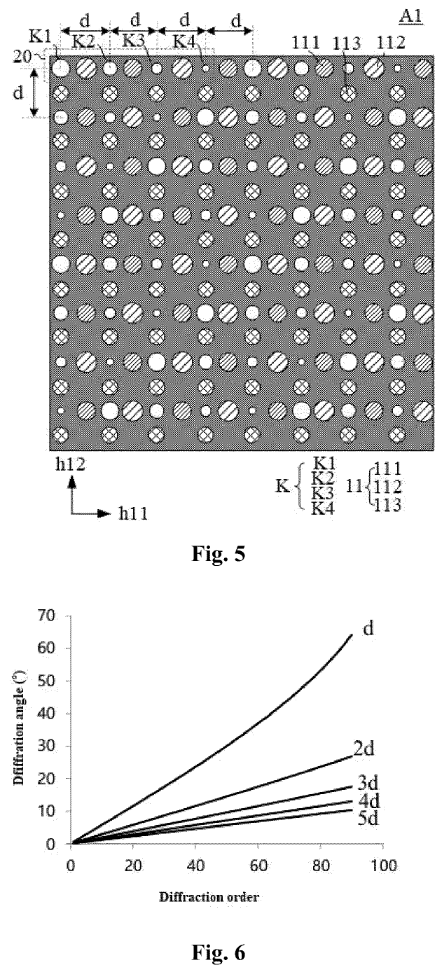

Exemplarily, in the embodiments of the present application, N satisfies: 2≤N≤6. In FIG. 2, N=2. Alternatively, as shown in FIG. 5, FIG. 5 is another enlarged schematic diagram of a first display area in FIG. 1, where N=4; that is, the light-transmitting aperture group 20 includes four light-transmitting apertures K having areas different from each other, and the four light-transmitting apertures K are the first light-transmitting aperture K1, the second light-transmitting aperture K2, the third light-transmitting aperture K3, and the fourth light-transmitting aperture K4, respectively. Based on the arrangement shown in FIG. 5, along the first direction h11, the distance between two light-transmitting apertures K having the same area in adjacent two of the light-transmitting aperture groups 20 may be 4d.

Exemplarily, as shown in FIG. 6, FIG. 6 is a diagram of diffraction curves under different grating constants according to embodiments of the present application. It may be seen that, as the grating constant is increased from d to 5d, the difference between the diffraction angles of adjacent two of the diffraction curves under the same diffraction order is gradually reduced, that is, the benefit brought by increasing the grating constant to reduce the diffraction angle is gradually reduced. In the embodiments of the present application, N≤6, so that disposing of excessive number of light-transmitting apertures having areas different from each other in the first display area A1 may prevented; since the light-transmitting apertures need to avoid the light-emitting elements when disposed, such design is beneficial for disposing more light-emitting elements in display panel and increasing the resolution of the display panel.

Optionally, under a condition that N≥3, that is, the light-transmitting aperture group 20 includes at least three light-transmitting apertures K having areas different from each other, in the embodiments of the present application, the plurality of light-transmitting apertures K may arranged in sequence along the first direction h11 in terms of the ascending order or the descending order of the area; or in the embodiments of the present application, the plurality of light-transmitting apertures K may be arranged not based on the dimension of the area to increase the irregularity of the arrangement of the light-transmitting apertures K and reduce the diffraction phenomenon.

Exemplarily, the N light-transmitting apertures K arranged along the first direction h11 and having areas different from each other in the light-transmitting aperture group 20 include the first light-transmitting aperture K1 to the N-th light-transmitting aperture; and in the embodiments of the present application, along the second direction h12, the first light-transmitting aperture K1 to the N-th light-transmitting aperture are alternately arranged in sequence.

Taking N=4 as an example, as shown in FIG. 5, the light-transmitting aperture group 20 includes the first light-transmitting aperture K1, the second light-transmitting aperture K2, the third light-transmitting aperture K3, and the fourth light-transmitting aperture K4 arranged along the first direction h11. Along the second direction h12, the first light-transmitting aperture K1, the second light-transmitting aperture K2, the third light-transmitting aperture K3, and the fourth light-transmitting aperture K4 are alternately arranged in sequence. Based on this arrangement, the arrangement of the light-transmitting apertures along the second direction h12 may be the same as the arrangement of the light-transmitting apertures along the first direction h11. That is, in FIG. 5, along the first direction h11 and the second direction h12, the plurality of light-transmitting apertures K are alternately arranged in sequence in the order of the first light-transmitting aperture K1, the second light-transmitting aperture K2, the third light-transmitting aperture K3, and the fourth light-transmitting aperture K4.

Exemplarily, in the embodiments of the present application, the distance between adjacent two of the light-transmitting apertures K in the same light-transmitting aperture group 20 is equal to the distance between adjacent two of the light-transmitting aperture groups 20. The distance between adjacent two of the light-transmitting apertures K refers to the distance between the geometric centers of adjacent two of the light-transmitting apertures K, and the distance between adjacent two of the light-transmitting aperture groups 20 refers to the distance between the geometric centers of two light-transmitting apertures K closest to each other located in the adjacent two of the light-transmitting aperture groups 20. Under a condition that N=4, that is, the light-transmitting aperture group 20 includes the first light-transmitting aperture K1, the second light-transmitting aperture K2, the third light-transmitting aperture K3, and the fourth light-transmitting aperture K4, as shown in FIG. 5, the distance between the first light-transmitting aperture K1 and the second light-transmitting aperture K2 adjacent to each other in the same light-transmitting aperture group 20 is d, and the distance between the fourth light-transmitting aperture K4 in one light-transmitting aperture group 20 and the first light-transmitting aperture K1 in another light-transmitting aperture group 20 adjacent to the one light-transmitting aperture group 20 is d. Based on this arrangement, the distance between any two light-transmitting apertures K having the same area located in adjacent two of the light-transmitting aperture groups 20 may be equal to each other. For example, under a condition that the light-transmitting aperture group 20 includes the first light-transmitting aperture K1 and the second light-transmitting aperture K2, the distance between adjacent two of the first light-transmitting apertures K1 may be equal to the distance between adjacent two of the second light-transmitting apertures K2, so that the diffraction angle of the light when it passes through the first light-transmitting aperture K1 may be equal to the diffraction angle of the light when it passes through the second light-transmitting aperture K2, and the intensity of the light passing through the first light-transmitting aperture K1 and received by the optical sensor may tend to be same as the intensity of the light passing through the second light-transmitting aperture K2 and received by the optical sensor, which is beneficial for increasing the consistency of the intensity of the light received by different parts of the optical sensor and improving the operation performance of the optical sensor.

Exemplarily, as shown in FIG. 1, the display panel further includes a second display area A2; the second display area A2 at least partially surrounds the first display area A1 and includes a plurality of sub-pixels.

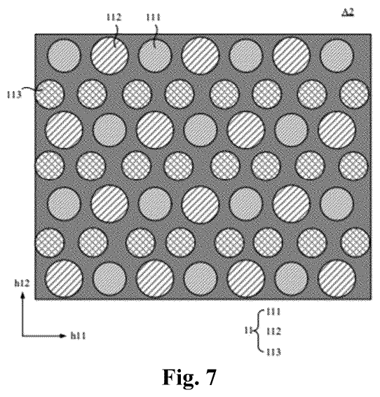

In the embodiments of the present application, the number of the sub-pixels in the second display area A2 is greater than or equal to the number of the sub-pixels in the first display area A1. Exemplarily, as shown in FIGS. 2 and 7, FIG. 7 is an enlarged schematic diagram of a second display area A2 in FIG. 1; it may be seen that, the density of the light-emitting elements in the second display area A2 is greater than the density of the light-emitting elements in the first display area A1, that is, the pixel density in the second display area A2 is greater than the pixel density in the first display area A1; based on this arrangement, the light transmittance of the first display area A1 may be increased, so that the light transmittance of the first display area A1 may be greater than the light transmittance of the second display area A2, the intensity of light entering the optical sensor corresponding to the first display area A1 may be increased, and the operation performance of the optical sensor may be improved. In addition, the resolution of the second display area A2 may be ensured, so that the second display area A2 has the desired display effect. In the operation of the optical sensor, the sub-pixels in the first display area A1 and the second display area A2 may jointly emit light, so that the display panel has the full-screen display effect.

Exemplarily, as shown in FIG. 7, the second display area A2 may not include the light-transmitting aperture.

It should be noted that, the pixel arrangement shown in FIGS. 2, 5, and 7 is only an example, and may actually be adjusted based on different design requirements, which is not limited by the embodiments of the present application.

Exemplarily, as shown in FIG. 3, the light-shielding layer 2 includes a first light-shielding layer 21 and a second light-shielding layer 22, and in the direction h2 perpendicular to the plane where the substrate 10 is located, the second light-shielding layer 22 is located at a side of the first light-shielding layer 21 close to the substrate 1.

The light-transmitting aperture K includes a first light-transmitting sub-aperture located in the first light-shielding layer 21 and a second light-transmitting sub-aperture located in the second light-shielding layer 22; taking an example that the light-transmitting aperture K includes the first light-transmitting aperture K1 and the second light-transmitting aperture K2 shown in FIG. 3; in order to distinguish, the first light-transmitting sub-aperture in the first light-transmitting aperture K1 is marked as K11, the second light-transmitting sub-aperture in the first light-transmitting aperture K1 is marked as K12, the first light-transmitting sub-aperture in the second light-transmitting aperture K2 is marked as K21, and the second light-transmitting sub-aperture in the second light-transmitting aperture K2 is marked as K22. On the plane where the substrate 10 is located, the orthographic projections of the first light-transmitting sub-aperture and the second light-transmitting sub-aperture in the same light-transmitting aperture K at least partially overlap. That is, on the plane where the substrate 10 is located, the orthographic projections of the first light-transmitting sub-aperture K11 and the second light-transmitting sub-aperture K12 in the first light-transmitting aperture K1 at least partially overlap, and the orthographic projections of the first light-transmitting sub-aperture K21 and the second light-transmitting sub-aperture K22 in the second light-transmitting aperture K2 at least partially overlap.

In the embodiments of the present application, in the same light-transmitting aperture K, the area of the second light-transmitting sub-aperture is greater than or equal to the area of the first light-transmitting sub-aperture. Exemplarily, on the plane where the substrate 10 is located, in the embodiments of the present application, the orthographic projection of the second light-transmitting sub-aperture may cover the orthographic projection of the first light-transmitting sub-aperture. In the process in which the ambient light casts to the optical sensor, the ambient light first passes through the first light-transmitting sub-aperture, and then passes through the second light-transmitting sub-aperture. Based on the arrangement according to the embodiments of the present application, the large-angle diffracted light diffracted through the edge of the first light-transmitting sub-aperture may pass through the second light-transmitting sub-aperture having a relatively great area, so that the diffracted light may cast to the optical sensor smoothly, which is beneficial to increasing the intensity of the light received by the optical sensor and improving the operation performance of the optical sensor.

Exemplarily, as shown in FIG. 3, the display panel includes a pixel definition layer (PDL) 23 and a black matrix (BM) 24; in the embodiments of the present application, the first light-shielding layer 21 includes the black matrix 24, and the second light-shielding layer 22 includes the pixel definition layer 23. That is, the black matrix 24 includes the first light-transmitting sub-aperture, and the pixel definition layer 23 includes the second light-transmitting sub-aperture.

Optionally, as shown in FIG. 3, the black matrix 24 is located at a side of the light-emitting element 11 away from the substrate 10; the black matrix 24 further includes the first opening OP1, and on the plane where the substrate 10 is located, the orthographic projection of the first opening OP1 at least partially overlaps with the orthographic projection of the light-emitting element 11; and the first opening OP1 may allow the light emitted by the light-emitting element 11 to pass through.

Exemplarily, as shown in FIG. 3, the display panel further includes a plurality of color filters (CF) 25, and the color filter 25 is located in the first opening OP1. The color filter 25 may carry out color filtering for the light emitted by the light-emitting element 11, so that the color of the light emitted by the color filter 25 satisfies the desired requirement.

As shown in FIG. 3, the pixel definition layer 23 further includes the second opening OP2, and the light-emitting element 11 includes the light-emitting layer 110, and at least a part of the light-emitting layer 110 is located in the second opening OP2. Exemplarily, the pixel definition layer 23 may be a black pixel definition layer to reduce the reflectivity of the display panel, increase the contrast ratio of the display panel, and increase the display effect of the display panel.

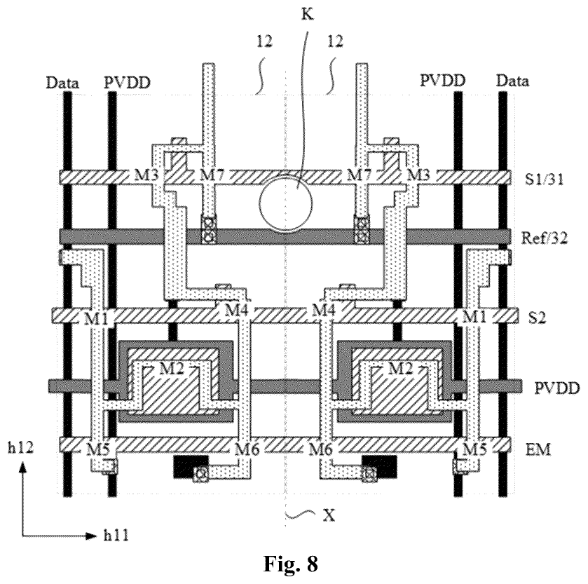

Optionally, as shown in FIG. 8, FIG. 8 is a schematic wiring diagram of a first display area according to embodiments of the present application; the sub-pixel further includes a pixel driving circuit 12 electrically connected to the light-emitting element; and the pixel driving circuit 12 is configured to control the driving current of the light-emitting element, so that the brightness of the light-emitting element is adjusted. In the embodiments of the present application, on the plane where the substrate is located, the orthographic projection of the light-transmitting aperture K is located between the orthographic projections of adjacent two of the pixel driving circuits 12 along the first direction h11, and adjacent two of the pixel driving circuits 12 are symmetrical. The “symmetrical” means that the same transistors in adjacent two of the pixel driving circuits 12 are symmetrical with respect to the axis of symmetry extending along the second direction h12.

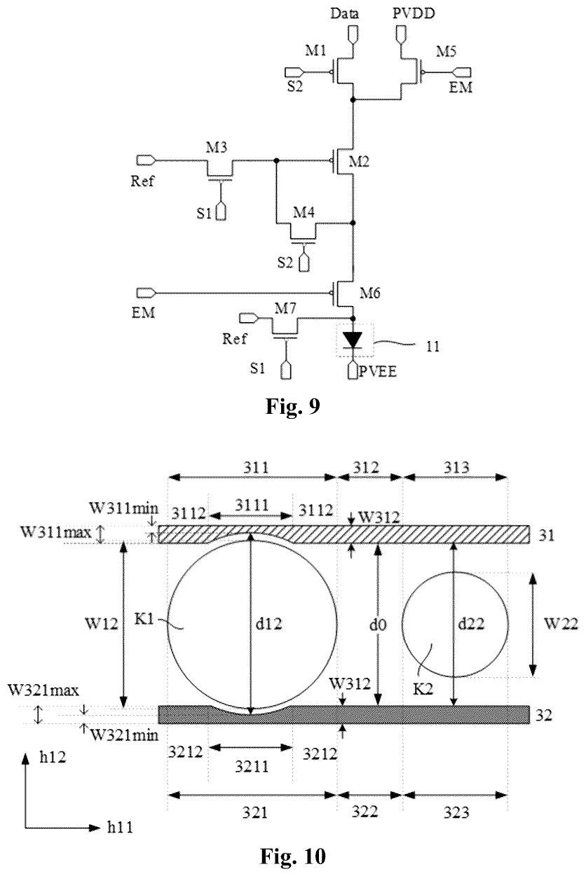

Exemplarily, as shown in FIGS. 8 and 9, FIG. 9 is a schematic diagram of a pixel driving circuit corresponding to FIG. 8 according to embodiments of the present application; and the pixel driving circuit 12 includes a data writing transistor M1, a drive transistor M2, a gate reset transistor M3, a threshold compensation transistor M4, a first light-emitting control transistor M5, a second light-emitting control transistor M6, and an anode reset transistor M7. The gate reset transistor M3 is configured to provide the reset signal Ref to the gate of the drive transistor M2 in response to the first scan signal S1. The anode reset transistor M7 is configured to provide the reset signal Ref to the anode of the light-emitting element 11 in response to the first scan signal S1. The data writing transistor M1 is configured to provide the data signal Data to the first terminal of the drive transistor M2 in response to the second scan signal S2, and the threshold compensation transistor M4 is electrically connected to the second terminal and the gate of the drive transistor M2 in response to the second scan signal S2. The first light-emitting control transistor M5 is configured to provide the first power supply signal PVDD to the first terminal of the drive transistor M2 in response to the light-emitting control signal EM. The second light-emitting control transistor M6 is electrically connected to the second terminal of the drive transistor M2 and the light-emitting element in response to the light-emitting control signal EM.

As shown in FIG. 8, the display panel further includes a plurality of signal wires electrically connected to the pixel driving circuits 12, and the signal wires include a first scan wire S1 (marked the same as the first scan signal transmitted by the first scan wire S1, the same applies to the below), a second scan wire S2, a light-emitting control wire EM, a data signal wire Data, a first power supply signal wire PVDD, a reset signal wire Ref, and the like.

The same transistors in the adjacent two of the pixel driving circuits 12 are symmetrical; that is, the data writing transistor M1 in one of the adjacent two of the pixel driving circuits 12 and the data writing transistor M1 in the other of the adjacent two of the pixel driving circuits 12 are symmetrical with respect to the axis X of symmetry extending along the second direction h12; the drive transistor M2 in one of the adjacent two of the pixel driving circuits 12 and the drive transistor M2 in the other of the adjacent two of the pixel driving circuits 12 are symmetrical with respect to the axis X of symmetry extending along the second direction h12; the gate reset transistor M3 in one of the adjacent two of the pixel driving circuits 12 and the gate reset transistor M3 in the other of the adjacent two of the pixel driving circuits 12 are symmetrical with respect to the axis X of symmetry extending along the second direction h12; the threshold compensation transistor M4 in one of the adjacent two of the pixel driving circuits 12 and the threshold compensation transistor M4 in the other of the adjacent two of the pixel driving circuits 12 are symmetrical with respect to the axis X of symmetry extending along the second direction h12; the first light-emitting control transistor M5 in one of the adjacent two of the pixel driving circuits 12 and the first light-emitting control transistor M5 in the other of the adjacent two of the pixel driving circuits 12 are symmetrical with respect to the axis X of symmetry extending along the second direction h12; the second light-emitting control transistor M6 in one of the adjacent two of the pixel driving circuits 12 and the second light-emitting control transistor M6 in the other of the adjacent two of the pixel driving circuits 12 are symmetrical with respect to the axis X of symmetry extending along the second direction h12; and the anode reset transistor M7 in one of the adjacent two of the pixel driving circuits 12 and the anode reset transistor M7 in the other of the adjacent two of the pixel driving circuits 12 are symmetrical with respect to the axis X of symmetry extending along the second direction h12.

In the embodiments of the present application, adjacent two of the pixel driving circuits 12 are symmetrical along the first direction h11, so that the light-shielding structures such as at least a part of the transistors and/or at least a part of the signal wires in the pixel driving circuit 12 located at one side of the light-transmitting aperture K may be disposed at the locations relatively distant from the light-transmitting aperture K in the pixel driving circuit 12, and the light-shielding structures such as at least a part of the transistors and/or at least a part of the signal wires in the pixel driving circuit 12 located at the other side of the light-transmitting aperture K may be disposed at the locations relatively distant from the light-transmitting aperture K in the pixel driving circuit 12. As shown in FIG. 8, in the embodiments of the present application, the first light-emitting control transistors M5 and the first power supply signal wires PVDD may be disposed at the locations relatively distant from the light-transmitting aperture K in the pixel driving circuit 12, so that the distance between the first power supply signal wires PVDD electrically connected to the two pixel driving circuits 12 along the first direction h11 may be increased, and under a condition that the light-transmitting aperture K is disposed between the two pixel driving circuits 12, the possibility that the light-transmitting aperture K is shielded by the first power supply signal wires PVDD and the first light-emitting control transistors M5 may be reduced, which is beneficial for reducing the disposing difficulty of the light-transmitting aperture K, increasing the light transmittance of the light-transmitting aperture, and increasing the light-transmitting area of the light-transmitting aperture K.

It should be noted that, the layout of the pixel driving circuit shown in FIG. 8 and the circuit structure of the pixel driving circuit shown in FIG. 9 are only examples, and other designs may actually be used, which is not limited by the embodiments of the present application.

Under a condition that the same light-transmitting aperture group 20 includes the first light-transmitting aperture K1 and the second light-transmitting aperture K2, on the plane where the substrate 10 is located, the orthographic projection of the first light-transmitting aperture K1 may be located between the orthographic projections of adjacent two of the pixel driving circuits 12 along the first direction h11, and the orthographic projection of the second light-transmitting aperture K2 may be located between the orthographic projections of other adjacent two of the pixel driving circuits 12 along the first direction h11.

Exemplarily, as shown in FIG. 8, the first display area A1 further includes a first signal wire 31 and a second signal wire 32 electrically connected to the pixel driving circuit 12, and the first signal wire 31 and the second signal wire 32 extend along the first direction h11; the first signal wire 31 and the second signal wire 32 are arranged along the second direction h12. On the plane where the substrate is located, the orthographic projections of the plurality of light-transmitting apertures K located in the same light-transmitting aperture group are located between the orthographic projection of the first signal wire 31 and the orthographic projection of the second signal wire 32 along the second direction h12.

Taking for the example that the light-transmitting aperture group 20 includes the first light-transmitting aperture K1 and the second light-transmitting aperture K2, as shown in FIGS. 10 to 15, which are simplified schematic diagrams of the first signal wire, the second signal wire, the first light-transmitting aperture, and the second light-transmitting aperture according to the embodiments of the present application; on the plane where the substrate is located, the orthographic projection of the first light-transmitting aperture K1 is located between the orthographic projection of the first signal wire 31 and the orthographic projection of the second signal wire 32, and the orthographic projection of the second light-transmitting aperture K2 is located between the orthographic projection of the first signal wire 31 and the orthographic projection of the second signal wire 32.

In the embodiments of the present application, as shown in FIGS. 10, to 15, the first signal wire 31 includes a first section 311, and the second signal wire 32 includes a second section 321; on the plane where the substrate is located, the edge of the orthographic projection of the first section 311 close to the first light-transmitting aperture K1 surrounds a part of the orthographic projection of the first light-transmitting aperture K1, and the edge of the orthographic projection of the second section 321 close to the first light-transmitting aperture K1 surrounds a part of the orthographic projection of the first light-transmitting aperture K1. Based on this arrangement, on the basis of ensuring that the signals transmitted by the first signal wire 31 and the second signal wire 32 can be normally transmitted, the first signal wire 31 and the second signal wire 32 may be prevented from shielding the first light-transmitting aperture K1, and the light transmittance of the first light-transmitting aperture K1 can be ensured.

It should be noted that the shapes of the first signal wire 31 and the second signal wire 32 shown in FIG. 10 are only examples; and under a condition that the entire first signal wire 31 extends along the first direction h11 and the entire second signal wire 32 extends along the first direction h11, in the embodiments of the present application, based on different design requirements, a broken line segment or a curved segment may further be disposed in the first signal wire 31 or the second signal wire 32.

Optionally, the first signal wire 31 and the second signal wire 32 may transmit different signals. In FIG. 8, it is shown that that the first signal wire 31 includes the first scan wire S1, and the second signal wire 32 includes the reset signal wire Ref.

Exemplarily, as shown in FIG. 10, the first signal wire 31 further includes a third section 312, and the second signal wire 32 further includes a fourth section 322; on the plane where the substrate is located, the orthographic projection of the third section 312 does not overlap with the orthographic projections of the light-transmitting apertures K in the light-transmitting aperture group 20 along the second direction h12, and the orthographic projection of the fourth section 322 does not overlap with the orthographic projections of the light-transmitting apertures K in the light-transmitting aperture group 20 along the second direction h12. Taking for the example that the light-transmitting aperture group 20 includes the first light-transmitting aperture K1 and the second light-transmitting aperture K2, on the plane where the substrate is located, the orthographic projection of the third section 312 does not overlap with the orthographic projection of the first light-transmitting aperture K1 along the second direction h12, and the orthographic projection of the third section 312 does not overlap with the orthographic projection of the second light-transmitting aperture K2 along the second direction h12; the orthographic projection of the fourth section 322 does not overlap with the orthographic projection of the first light-transmitting aperture K1 along the second direction h12, and the orthographic projection of the fourth section 322 does not overlap with the orthographic projection of the second light-transmitting aperture K2.

In the embodiments of the present application, the width of the first section 311 is less than or equal to the width W312 of the third section 312; and/or the width of the second section 321 is less than or equal to the width W322 of the fourth section 322.

Exemplarily, the first section 311 may be a straight-line section, or may be a non-straight-line section having different widths at different locations as shown in FIG. 10; under a condition that the first section 311 is the non-straight-line section, the first section 311 may have different widths at different locations. As shown in FIG. 10, the minimum width of the first section 311 is W311min, and the maximum width is W311max. W311min<W311max. The width of the first section 311 refers to the minimum width W311min of the first section 311.

Similarly, under a condition that the second section 321 is the non-straight-line section, the second section 321 may have different widths at different locations. As shown in FIG. 10, the minimum width of the second section 321 is W321min, and the maximum width is W321max. W321min<W321max. The width of the second section 321 refers to the minimum width W 321 min of the second section 321.

In the embodiments of the present application, the width of the first section 311 and/or the second section 321 is reduced, so that the first section 311 and/or the second section 321 may avoid the first light-transmitting aperture K1, which is beneficial for ensuring the light transmittance of the first light-transmitting aperture K1.

Exemplarily, as shown in FIG. 10, on the plane where the substrate is located, the edge of the orthographic projection of the first section 311 away from the first light-transmitting aperture K1 is the straight line in shape; and/or the edge of the orthographic projection of the second section 321 away from the first light-transmitting aperture K1 is the straight line in shape. Based on this arrangement, the uniformity of the shape of the edge of the first signal wire 31 and/or the second signal wire 32 away from the first light-transmitting aperture K1 may be increased.

Still referring to FIG. 10, on the plane where the substrate is located, the edge of the orthographic projection of the third section 312 away from the first light-transmitting aperture K1 is the straight line in shape, and the edge of the orthographic projection of the fourth section 322 away from the first light-transmitting aperture K1 is the straight line in shape. Optionally, the edge of the orthographic projection of the first section 311 away from the first light-transmitting aperture K1 may be parallel to the edge of the orthographic projection of the third section 312 away from the first light-transmitting aperture K1. The edge of the orthographic projection of the second section 321 away from the first light-transmitting aperture K1 may be parallel to the edge of the orthographic projection of the fourth section 322 away from the first light-transmitting aperture K1.

Exemplarily, as shown in FIG. 10, the first section 311 includes a first sub-section 3111 and a second sub-section 3112, a side of the first sub-section 3111 close to the first light-transmitting aperture K1 has a notch, and the second sub-section 3112 does not include a notch. The first sub-section 3111 may be seen as being formed by removing a part close to the first light-transmitting aperture K1 on the basis of the third section 312. The second section 321 includes the third sub-section 3211 and the fourth sub-section 3212, a side of the third sub-section 3211 close to the first light-transmitting aperture K1 has a notch, and the fourth sub-section 3212 does not include a notch. The third sub-section 3211 may be seen as being formed by removing a part close to the first light-transmitting aperture K1 on the basis of the fourth section 322.

It should be noted that, the circular shape of the first light-transmitting aperture K1 shown in FIG. 10 is only an example, and in the embodiments of the present application, the shape of the first light-transmitting aperture K1 may be designed to be a polygon or an irregular shape based on different design requirements. Accordingly, the shapes of the edges of the first section 311 and the second section 321 close to the first light-transmitting aperture K1 may be designed to be a straight line, a broken line, a curve, or other shapes, which is not limited by the embodiments of the present application.

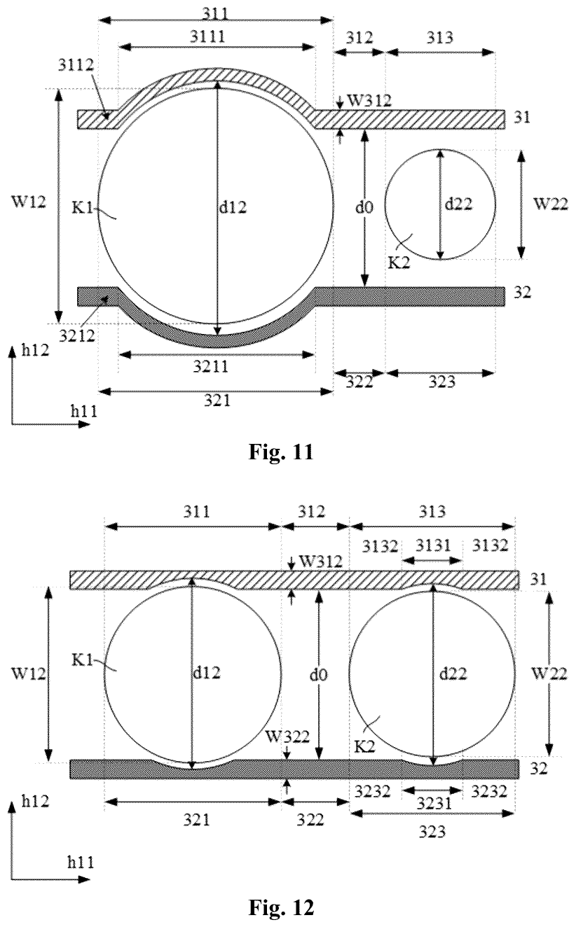

Optionally, as shown in FIG. 11, at least a part of the first section 311 is convex toward the direction away from the first light-transmitting aperture K1; and/or at least a part of the second section 321 is convex toward the direction away from the first light-transmitting aperture K1. Based on this arrangement, the area in which the first light-transmitting aperture K1 may be disposed may be increased, which is beneficial for increasing the light-transmitting area of the first light-transmitting aperture K1, and increasing the light transmittance of the first display area A1.

Exemplarily, as shown in FIG. 11, the first section 311 includes the first sub-section 3111 and the second sub-section 3112, the first sub-section 3111 is convex toward the direction away from the first light-transmitting aperture K1, and the second sub-section 3112 may not protrude. The second section 321 includes a third sub-section 3211 and a fourth sub-section 3212, the third sub-section 3211 is convex toward the direction away from the first light-transmitting aperture K1, and the fourth sub-section 3212 may not protrude.

Optionally, as shown in FIGS. 10 and 11, the first signal wire 31 further includes a fifth section 313 corresponding to the second light-transmitting aperture K2, and the second signal wire 32 further includes a sixth section 323 corresponding to the second light-transmitting aperture K2; on the plane where the substrate is located, the orthographic projection of the edge of the fifth section 313 close to the second light-transmitting aperture K2 the straight line in shape; and/or the orthographic projection of the edge of the sixth section 323 close to the second light-transmitting aperture K2 is the straight line in shape.

Exemplarily, as shown in FIGS. 10 and 11, the maximum width W22 of the second light-transmitting aperture K2 along the second direction h12 is less than the shortest distance d0 between the third section 312 and the fourth section 322. The shortest distance between the third section 312 and the fourth section 322 may be the distance between the edges of the third section 312 and the fourth section 322 on a side close to the light-transmitting aperture K. Under this condition, in order to dispose the second light-transmitting aperture K2, in the embodiments of the present application, there may be no need for additional adjustment to the fifth section 313 and the sixth section 323. For example, as shown in FIG. 10 and FIG. 11, in the embodiments of the present application, the shape of the fifth section 313 may be designed to be the same as the shape of the third section 312, and the shape of the sixth section 323 may be designed to be the same as the shape of the fourth section 322. For example, on the plane where the substrate is located, in the embodiments of the present application, the orthographic projection of the fifth section 313 and the orthographic projection of the third section 312 may be designed to be the straight lines with extending directions parallel to each other, and the orthographic projection of the sixth section 323 and the orthographic projection of the fourth section 322 may be designed to be the straight lines with extending directions parallel to each other. With such design, in one aspect, the uniformity of the shape of the first signal wire 31 and/or the second signal wire 32 at different locations may be increased; in another aspect, the lengths of the fifth section 313 and the sixth section 323 may be reduced, and the voltage drop during the signal transmission may be reduced.

Optionally, as shown in FIGS. 12 to 15, on the plane where the substrate is located, in the embodiments of the present application, the edge of the orthographic projection of the fifth section 313 close to the second light-transmitting aperture K2 may surround a part of the orthographic projection of the second light-transmitting aperture K2, and/or the edge of the orthographic projection of the sixth section 323 close to the second light-transmitting aperture K2 may surround a part of the orthographic projection of the second light-transmitting aperture K2.

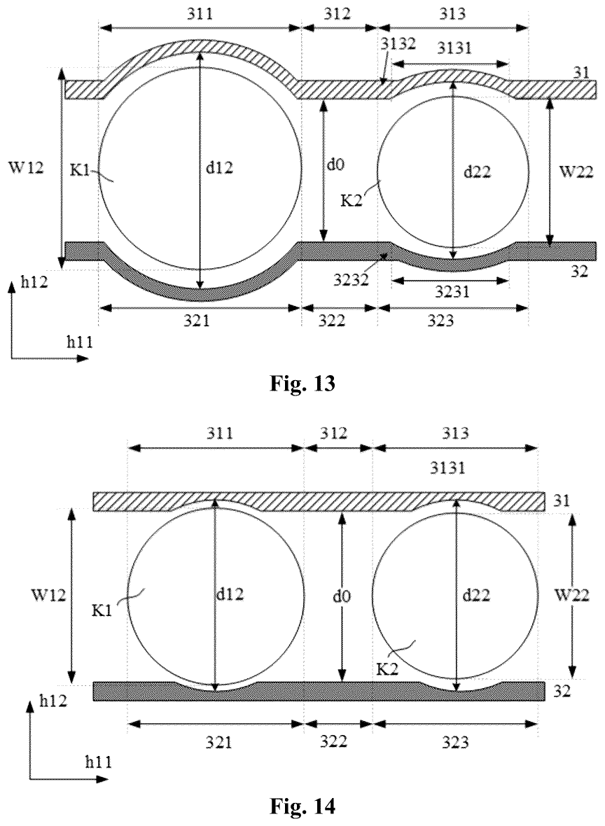

Based on the above arrangement, under a condition that the second light-transmitting aperture K2 is designed, exemplarily, as shown in FIGS. 12 and 13, in the embodiments of the present application, the maximum width W22 of the second light-transmitting aperture K2 along the second direction h12 may be greater than or equal to the minimum distance d0 between the third section 312 and the fourth section 322, so that the area of the second light-transmitting aperture K2 is increased, and the intensity of the ambient light transmitting the second light-transmitting aperture K2 is increased.

Optionally, as shown in FIG. 13, in the embodiments of the present application, at least a part of the fifth section 313 may protrude toward the direction away from the second light-transmitting aperture K2; and/or the sixth section 323 may protrude toward the direction away from the second light-transmitting aperture K2, so that the area in which the second light-transmitting aperture K2 may be disposed may be increased, the light-transmitting area of the second light-transmitting aperture K2 may be increased, and the light transmittance of the first display area A1 may be increased.

Exemplarily, as shown in FIG. 13, the fifth section 313 includes the fifth sub-section 3131 and the sixth sub-section 3132, the fifth sub-section 3131 is convex toward the direction away from the second light-transmitting aperture K2, and the sixth sub-section 3132 may not protrude. The sixth section 323 includes the seventh sub-section 3231 and the eighth sub-section 3232, the seventh sub-section 3231 is convex in the direction away from the second light-transmitting aperture K2, and the eighth sub-section 3232 may not protrude.

Optionally, in the embodiments of the present application, the width of the fifth section 313 may be less than or equal to the width W312 of the third section 312; and/or the width of the sixth section 323 may be less than or equal to the width W322 of the fourth section 322.

In the embodiments of the present application, the fifth section 313 may be the straight-line section as shown in FIGS. 10 and 11, or may be the non-straight-line section having different widths at different locations as shown in FIG. 12; under a condition that the fifth section 313 is the non-straight-line section, the fifth section 313 may have different widths at different locations. The width of the fifth section 313 refers to the minimum width of the fifth section 313; similarly, the width of the sixth section 323 refers to the minimum width of the sixth section 323.

In FIGS. 10 and 11, it is shown that the width of the fifth section 313 is equal to the width W312 of the third section 312, and the width of the sixth section 323 is equal to the width W322 of the fourth section 322.

In FIG. 12, it is shown that the width of the fifth section 313 is less than the width W312 of the third section 312, and the width of the sixth section 323 is less than the width W322 of the fourth section 322; based on this arrangement, the fifth section 313 and the sixth section 323 may avoid the second light-transmitting aperture K2, which is beneficial for ensuring the light transmittance of the second light-transmitting aperture K2.

Exemplarily, as shown in FIGS. 10 to 12, on the plane where the substrate is located, the orthographic projection of the edge of the fifth section 313 away from the second light-transmitting aperture K2 is the straight line in shape; and/or the orthographic projection of the sixth section 323 away from the second light-transmitting aperture K2 is the straight line in shape. Based on this arrangement, the uniformity of the shape of the edge of the first signal wire 31 and/or the second signal wire 32 away from the second light-transmitting aperture K2 may be increased.

Optionally, as shown in FIGS. 10 to 12, on the plane where the substrate is located, the edge of the orthographic projection of the third section 312 away from the second light-transmitting aperture K2 is the straight line in shape, and the edge of the orthographic projection of the fourth section 322 away from the second light-transmitting aperture K2 is the straight line in shape. Exemplarily, the edge of the orthographic projection of the fifth section 313 away from the second light-transmitting aperture K2 may be parallel to the edge of the orthographic projection of the third section 312 away from the second light-transmitting aperture K2. The edge of the orthographic projection of the sixth section 323 away from the second light-transmitting aperture K2 may be parallel to the edge of the orthographic projection of the fourth section 322 away from the second light-transmitting aperture K2.

Exemplarily, as shown in FIG. 12, the fifth section 313 includes the fifth sub-section 3131 and the sixth sub-section 3132, and a side of the fifth sub-section 3131 close to the second light-transmitting aperture K2 has a notch, and the sixth sub-section 3132 may not include a notch. The sixth section 323 includes a seventh sub-section 3231 and an eighth sub-section 3232, a side of the seventh sub-section 3231 close to the second light-transmitting aperture K2 has a notch, and the eighth sub-section 3232 may not include a notch. The fifth sub-section 3131 may be seen as being formed by removing a part close to the second light-transmitting aperture K2 on the basis of the third section 312. The seventh sub-section 3231 may be seen as being formed by removing a part close to the second light-transmitting aperture K2 on the basis of the fourth section 322.

It should be noted that the circular shape of the second light-transmitting aperture K2 shown in FIGS. 10 to 12 is only an example, and in the embodiments of the present application, the shape of the light-transmitting aperture may be designed to be a polygon or an irregular shape based on different design requirements. Accordingly, the shapes of the edges of the fifth section 313 and the sixth section 323 close to the edge of the second light-transmitting aperture K2 may be designed to be a straight line, a broken line, a curve, or other shapes, which is not limited by the embodiments of the present application.

Exemplarily, in the embodiments of the present application, the width of the fifth section 313 is greater than or equal to the width W311 of the first section 311; and/or the width W323 of the sixth section 323 is greater than or equal to the width W321 of the second section 321. The widths of the structures refer to the minimum widths thereof. Based on this arrangement, the widths of the first signal wire 31 and the second signal wire 32 at different locations may be adapted to the areas of the light-transmitting apertures corresponding to these locations, which is beneficial for ensuring the areas of the light-transmitting apertures K.

In FIG. 12, it is shown that the width of the fifth section 313 is greater than the width W311 of the first section 311.

Alternatively, in FIG. 13, it is shown that the width W313 of the fifth section 313 is equal to the width W311 of the first section 311, and the width W323 of the sixth section 323 is equal to the width W321 of the second section 321. Based on this arrangement, the uniformity of the widths of the first signal wire 31 and the second signal wire 32 at different locations may be increased, which is beneficial for increasing the consistency of the resistance of the first signal wire 31 at different locations and the consistency of the resistance of the second signal wire 32 at different locations, and is beneficial for the stable transmission of the signal.

Exemplarily, as shown in FIGS. 10 to 12, and FIG. 13, the maximum length of the first light-transmitting aperture K1 along the second direction h12 is W12, the maximum length of the second light-transmitting aperture K2 along the second direction h12 is W22, and W12>W22, so that the area of the first light-transmitting aperture K1 is greater than the area of the second light-transmitting aperture K2.

As shown in FIGS. 10 to 13, along the second direction h12, the distance between the first section 311 and the second section 321 is d12, and the distance between the fifth section 313 and the sixth section 323 is d22; the distance between the first section 311 and the second section 321 refers to the maximum distance between the edge of the first section 311 close to the second section 321 and the edge of the second section 321 close to the first section 311. The distance between the fifth section 313 and the sixth section 323 refers to the maximum distance between the edge of the fifth section 313 close to the sixth section 323 and the edge of the sixth section 323 close to the fifth section 313. In the embodiments of the present application, d12≥d22.

In FIGS. 10 to 13, it is shown that d12>d22. Based on this arrangement, the distance between the first section 311 and the second section 321 corresponding to the first light-transmitting aperture K1 and the distance between the fifth section 313 and the sixth section 323 corresponding to the second light-transmitting aperture K2 may be adapted to the dimensions of the first light-transmitting aperture K1 and the second light-transmitting aperture K2, respectively, so that the space in the display panel may be reasonably utilized.

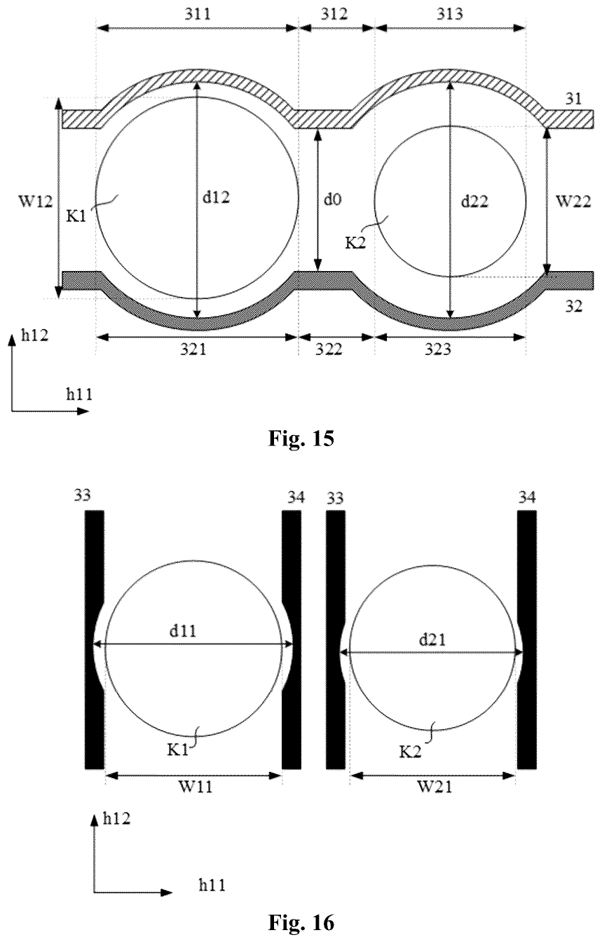

Alternatively, FIGS. 14 and 15 both show that d12=d22 for illustration. In the embodiments of the present application, d12=d22. In one aspect, the shapes of the first signal wire 31 and the second signal wire 32 at different locations tend to be consistent, so that the consistency of the shape and the length is increased, and the transmission of the signal at different locations may tend to be consistent. In another aspect, the distance between the second light-transmitting aperture K2 having a relatively small area and the first signal wire 31 may be increased, and/or the distance between the second light-transmitting aperture K2 having a relatively small area and the second signal wire 32 may be increased, which is beneficial for increasing the amount of light transmitting the second light-transmitting aperture K2.

Exemplarily, as shown in FIG. 16, FIG. 16 is a simplified schematic diagram of a third signal wire, a fourth signal wire, a first light-transmitting aperture, and a second light-transmitting aperture according to embodiments of the present application; the first display area A1 further includes the third signal wire 33 and the fourth signal wire 34, and the third signal wire 33 and the fourth signal wire 34 both extend along the second direction h12; the third signal wire 33 and the fourth signal wire 34 are arranged along the first direction h11; and the third signal wire 33 and the fourth signal wire 34 are electrically connected to adjacent two of the pixel driving circuits 12.

On the plane where the substrate is located, along the first direction h11, the orthographic projection of the first light-transmitting aperture K1 is located between the orthographic projections of one group of third signal wire 33 and fourth signal wire 34; and the orthographic projection of the second light-transmitting aperture K2 is located between the orthographic projections of the other group of third signal wire 33 and fourth signal wire 34.

Exemplarily, as shown in FIG. 16, the maximum length of the first light-transmitting aperture K1 along the first direction h11 is W11, the maximum length of the second light-transmitting aperture K2 along the first direction h11 is W21, and W11>W21; with this arrangement, the area of the first light-transmitting aperture K1 is greater than the area of the second light-transmitting aperture K2.

As shown in FIG. 16, the distance between the third signal wire 33 and the fourth signal wire 34 located at two sides of the first light-transmitting aperture K1 is d11, and the distance between the third signal wire 33 and the fourth signal wire 34 located at two sides of the second light-transmitting aperture K2 is d21; the distance between the third signal wire 33 and the fourth signal wire 34 refers to the maximum distance between the edge of the third signal wire 33 close to the fourth signal wire 34 and the edge of the fourth signal wire 34 close to the third signal wire 33. In the embodiments of the present application, d11≥d21.

In FIG. 16, it is shown that d11>d21; based on this arrangement, the distance between the third signal wire 33 and the fourth signal wire 34 corresponding to the first light-transmitting aperture K1 and the distance between the third signal wire 33 and the fourth signal wire 34 corresponding to the second light-transmitting aperture K2 may be adapted to the dimensions of the first light-transmitting aperture K1 and the second light-transmitting aperture K2, respectively, so that the space in the display panel may be reasonably utilized.

Alternatively, as shown in FIG. 17, FIG. 17 is another simplified schematic diagram of a third signal wire, a fourth signal wire, a first light-transmitting aperture, and a second light-transmitting aperture according to embodiments of the present application, in which it is also satisfied that d11=d21. In one aspect, the shapes of different third signal wires 33 at different locations may tend to be consistent, and the shapes of different fourth signal wires 34 at different locations may tend to be consistent, so that the consistency of the shapes and the lengths of the signal wires transmitting the same type of signal is increased, and the transmission of the signals at different locations may tend to be consistent. In another aspect, the distance between the second light-transmitting aperture K2 having a relatively small area and the third signal wire 33 may be increased, and/or the distance between the second light-transmitting aperture K2 having a relatively small area and the fourth signal wire 34 may be increased, so that the amount of light transmitting the second light-transmitting aperture K2 may be increased.

Exemplarily, the type of the signals transmitted by different third signal wires 33 corresponding to the first light-transmitting aperture K1 and the second light-transmitting aperture K2 may be the same; for example, different third signal wires 33 corresponding to the first light-transmitting aperture K1 and the second light-transmitting aperture K2 both may transmit the data signal Data, that is, different third signal wires 33 corresponding to the first light-transmitting aperture K1 and the second light-transmitting aperture K2 both include the data signal wire; alternatively, different third signal wires 33 corresponding to the first light-transmitting aperture K1 and the second light-transmitting aperture K2 both may transmit the first power supply signal PVDD, that is, different third signal wires 33 corresponding to the first light-transmitting aperture K1 and the second light-transmitting aperture K2 both may include the first power supply signal wire.

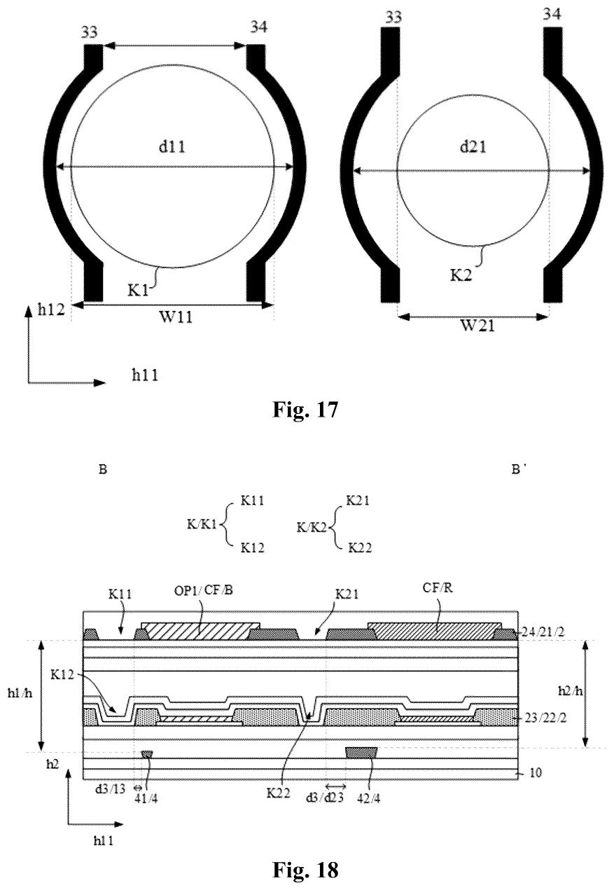

Exemplarily, as shown in FIG. 18, FIG. 18 is another schematic cross-sectional diagram taken along BB′ in FIG. 2, in which the display panel further includes a light-shielding metal 4 located between the light-shielding layer 2 and the substrate 10, and in the direction h2 perpendicular to the plane where the substrate 10 is located, the light-shielding metal 4 does not overlap with the light-transmitting aperture K. The light-shielding metal 4 can receive the diffracted light emitted from the light-transmitting aperture K and reflect the received diffracted light, and the included angle between the propagation direction of the reflected light and the normal line of the substrate 10 is less than the included angle between the diffracted light entering the light-shielding metal 4 and the normal line of the substrate 10.

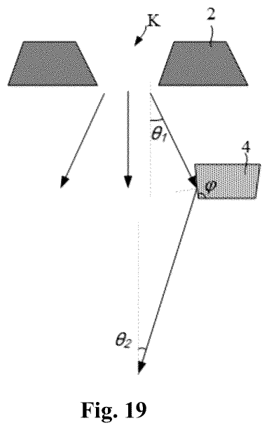

Specifically, in the process in which the ambient light casts from the first side of the display panel to the second side of the display panel through the light-transmitting aperture K, as shown in FIG. 19, FIG. 19 is a schematic diagram of an optical path along which ambient light passes through a light-transmitting aperture and a light-shielding metal, the light diffracted by the light-transmitting aperture K may be reflected by the side surface of the light-shielding metal 4, in the direction parallel to the plane where the substrate is located, the side surface of the light-shielding metal 4 is located at a side of the light-shielding metal 4 close to the light-transmitting aperture K, and the included angle θ_2 between the propagation direction of the reflected light and the normal line of the substrate is less than the included angle θ_1 between the diffracted light entering the light-shielding metal 4 and the normal line of the substrate 10, that is, by disposing the light-shielding metal 4, the large-angle diffracted light transmitting the light-transmitting aperture K may be adjusted to be the small-angle light, so that the intensity of light entering the optical sensor located at the second side of the display panel may be increased, and the utility rate of the ambient light may be increased.

For example, the light-shielding metal 4 includes a structure such as the signal wire or the source and the drain of the thin film transistor.

Optionally, in the embodiments of the present application, the angle between the side surface and the bottom surface of the light-shielding metal 4 is φ, where 92.5°≤φ≤100°

In the embodiments of the present application, φ≤100°, the diffracted light emitted through the light-transmitting aperture K and having the included angle greater than equal to 10° between the propagation direction and the normal line of the substrate 10 may cast to the side surface of the light-shielding metal 4, and the intensity of the diffracted light received by the light-shielding metal 4 may be increased, so that the intensity of the ambient light reflected into the optical sensor is increased.

Further, reference is made to FIG. 19, where

$${θ}_{2} = 180 ° - {θ}_{1} - 2 \times ( φ - {θ}_{1} ) = 180 ° - 2 φ + {θ}_{1} . \qquad ( 2 )$$

In the embodiments of the present application, 92.5°≤φ, which may be substituted into the formula (2) to obtain:

$${θ}_{2} \leq {θ}_{1} - 5 ° \qquad ( 3 )$$

Exemplarily, the maximum diffraction angle θ₁=10° obtained under a condition that five light-transmitting apertures K having areas different from each other are disposed in the light-transmitting aperture group 20 (that is, under a condition that N=5) may be taken to the formula (3) to obtain θ₂≤5°; that is, in the embodiments of the present application, 92.5°≤φ1, the included angle between the propagation direction of the light reflected by the first light-shielding metal 41 and the substrate 10 may be less than equal to 5°, so that the intensity of the ambient light entering the optical sensor can be increased, and the operation performance of the optical sensor can be increased.

Optionally, as shown in FIG. 18, in the direction parallel to the plane where the substrate 10 is located, the distance between the edge of the light-shielding metal 4 and the edge of the light-transmitting aperture K is d3, and in the direction perpendicular to the plane where the substrate 10 is located, the distance between the light-shielding metal 4 and the light-shielding layer 2 is h, where d3≤h×tan 10°. Based on this arrangement, the large-angle diffracted light emitted from the light-transmitting aperture K, that is, the diffracted light having the included angle greater than or equal to 10° between the propagation direction and the normal line of the substrate 10, may cast to the side surface of the corresponding light-shielding metal 4 and may further be reflected by the side surface of the light-shielding metal 4, which is beneficial for increasing the utility rate of the diffracted light emitted through the light-transmitting aperture K.

Exemplarily, taking for the example that the light-transmitting aperture group 20 includes the first light-transmitting aperture K1 and the second light-transmitting aperture K2, as shown in FIG. 18, the light-shielding metal 4 includes a first light-shielding metal 41 and a second light-shielding metal 42, in the direction perpendicular to the plane where the substrate 10 is located, the first light-shielding metal 41 does not overlap with the first light-transmitting aperture K1, and the second light-shielding metal 42 does not overlap with the second light-transmitting aperture K2. The first light-shielding metal 41 may receive the diffracted light emitted from the first light-transmitting aperture K1, and the second light-shielding metal 42 may receive the diffracted light emitted from the second light-transmitting aperture K2.

In the embodiments of the present application, the angle between the side surface and the bottom surface of the first light-shielding metal 41 is φ1, and the included angle between the side surface and the bottom surface of the second light-shielding metal 42 is φ2, where 92.5°≤φ1≤100°, so that the more diffracted light emitted through the first light-transmitting aperture K1 and having the included angle greater than or equal to 10° between the propagation direction and the normal line of the substrate 10 may cast to the side surface of the first light-shielding metal 41, that is, the intensity of the diffracted light received by the first light-shielding metal 41 is increased, and the intensity of the ambient light reflected by the first light-shielding metal 41 to the optical sensor is increased. Additionally or alternatively, 92.5°≤φ2≤100°, so that the more diffracted light emitted through the second light-transmitting aperture K2 and having the included angle greater than or equal to 10° between the propagation direction and the normal line of the substrate 10 may cast to the side surface of the second light-shielding metal 42, that is, the intensity of the diffracted light received by the second light-shielding metal 42 is increased, and the intensity of the ambient light reflected by the second light-shielding metal 42 to the optical sensor is increased.

As shown in FIG. 18, the distance between the edge of the first light-shielding metal 41 and the edge of the first light-transmitting aperture K1 is d13, and the distance between the edge of the second light-shielding metal 42 and the edge of the second light-transmitting aperture K2 is d23; in the direction perpendicular to the plane where the substrate 10 is located, the distance between the second light-shielding metal 42 and the first light-shielding layer 21 is h1, and the distance between the second light-shielding metal 42 and the first light-shielding layer 21 is h2, where d13≤h1×tan 10°, so that the large-angle diffracted light emitted from the first light-transmitting aperture K1 may cast to the side surface of the first light-shielding metal 41 and may further be reflected by the side surface of the first light-shielding metal 41, which is beneficial for increasing the utility rate of the diffracted light emitted through the first light-transmitting aperture K1. Additionally or alternatively, in the embodiments of the present application, d23≤h2×tan 10°, so that the large-angle diffracted light emitted from the second light-transmitting aperture K2 may cast to the side surface of the second light-shielding metal 42 and may further be reflected by the side surface of the second light-shielding metal 42, which is beneficial for increasing the utility rate of the diffracted light emitted through the second light-transmitting aperture K2.

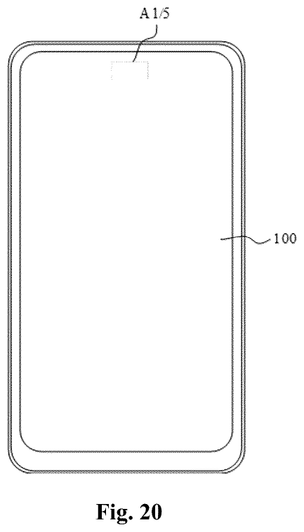

Based on the same inventive concept, embodiments of the present application further provide a display apparatus, as shown in FIG. 20, FIG. 20 is a schematic diagram of a display apparatus according to embodiments of the present application, and the display apparatus includes an optical sensor 5 and the display panel 100. The orthographic projection of the optical sensor 5 on the plane where the substrate is located is at least partially located in the first display area A1. The specific structure of the display panel 100 has been described in detail in the above embodiments, which is not repeated herein. Of course, the display apparatus shown in FIG. 20 is only an example, and may be any device having a display function, such as a mobile phone, a tablet computer, a notebook computer, an electronic paper book, a television, or a smart watch, which is not limited by the embodiments of the present application.

The above are only the preferred embodiments of the present application, and are not intended to limit the present application. Any modifications, equivalents, improvements, or the like made within the gist and principle of the present application shall be included within the protection scope of the present application.

What is claimed is:

1. A display panel comprising a first display area, the first display area comprising a plurality of sub-pixels comprising light-emitting elements;
the display panel further comprising:
a substrate; and
a light-shielding layer located at a side of the substrate, wherein
the light-shielding layer comprises a plurality of light-transmitting aperture groups located in the first display area,
the plurality of light-transmitting aperture groups are arranged in an array along a first direction and a second direction,
the plurality of light-transmitting aperture groups each comprise N light-transmitting apertures arranged along the first direction and having areas different from each other, where N is an integer and N≥2, and
in a direction perpendicular to a plane where the display panel is located, the light-transmitting apertures do not overlap with the light-emitting elements.

2. The display panel according to claim 1, wherein
along the first direction, a distance between adjacent two of the light-transmitting aperture groups is equal to a distance between adjacent two of the light-transmitting apertures in a same one of the light-transmitting aperture groups.

3. The display panel according to claim 1, wherein
the light-shielding layer comprises a first light-shielding layer and a second light-shielding layer located at a side of the first light-shielding layer close to the substrate;
the light-transmitting aperture comprise a first light-transmitting sub-aperture located in the first light-shielding layer and a second light-transmitting sub-aperture located in the second light-shielding layer,
on a plane where the substrate is located, an orthographic projection of the first light-transmitting sub-aperture at least partially overlaps with an orthographic projection of the second light-transmitting sub-aperture; and
on the plane where the substrate is located, an area of the orthographic projection of the second light-transmitting sub-aperture is greater than or equal to an area of the orthographic projection of the first light-transmitting sub-aperture.

4. The display panel according to claim 3, the display panel further comprising a black matrix and a pixel definition layer, wherein
the black matrix is located at a side of the light-emitting element away from the substrate and further comprises a first opening which overlaps with one of the light-emitting elements in the direction perpendicular to the plane where the display panel is located;
the pixel definition layer comprises a second opening, the light-emitting elements comprise a light-emitting layer which is at least partially located within the second opening; and
the first light-shielding layer comprises the black matrix, and the second light-shielding layer comprises the pixel definition layer.

5. The display panel according to claim 1, wherein
the sub-pixels further comprise pixel driving circuits electrically connected to the light-emitting elements;
on the plane where the substrate is located, an orthographic projection of one of the light-transmitting apertures is located between orthographic projections of adjacent two of the pixel driving circuits along the first direction, and
the adjacent two of the pixel driving circuits are symmetrical.

6. The display panel according to claim 5, wherein
the first display area further comprises a first signal wire and a second signal wire that are electrically connected to the pixel driving circuits and extend along the first direction and arranged along the second direction;
on the plane where the substrate is located, orthographic projections of a plurality of the light-transmitting apertures in a same one of the light-transmitting aperture groups are located between an orthographic projection of the first signal wire and an orthographic projection of the second signal wire;
the plurality of the light-transmitting apertures in the same one of the light-transmitting aperture groups comprise at least a first light-transmitting aperture,
the first signal wire comprises a first section, and on the plane where the substrate is located, an edge of an orthographic projection of the first section close to the first light-transmitting aperture surrounds a part of an orthographic projection of the first light-transmitting aperture, and
the second signal wire comprises a second section, and on the plane where the substrate is located, an edge of an orthographic projection of the second section close to the first light-transmitting aperture surrounds a part of the orthographic projection of the first light-transmitting aperture.

7. The display panel according to claim 6, wherein
the first signal wire comprises a third section, and the second signal wire comprises a fourth section;
on the plane where the substrate is located, an orthographic projection of the third section does not overlap with the orthographic projections of the plurality of the light-transmitting apertures in the same one of the light-transmitting aperture groups along the second direction, and an orthographic projection of the fourth section does not overlap with the orthographic projections of the plurality of the light-transmitting apertures in the same one of the light-transmitting aperture groups along the second direction; and
a width of the first section is less than a width of the third section, and/or a width of the second section is less than a width of the fourth section.

8. The display panel according to claim 7, wherein
on the plane where the substrate is located, an edge of the orthographic projection of the first section away from the first light-transmitting aperture is a straight line in shape;
and/or, on the plane where the substrate is located, an edge of the orthographic projection of the second section away from the first light-transmitting aperture is a straight line in shape.

9. The display panel according to claim 6, wherein
the first section is convex toward a direction away from the first light-transmitting aperture; and/or the second section is convex toward the direction away from the first light-transmitting aperture.

10. The display panel according to claim 6, wherein
the plurality of the light-transmitting apertures in the same one of the light-transmitting aperture groups further comprise at least a second light-transmitting aperture,
the first signal wire further comprises a fifth section corresponding to the second light-transmitting aperture, and the second signal wire further comprises a sixth section corresponding to the second light-transmitting aperture; and
on the plane where the substrate is located, an orthographic projection of an edge of the fifth section close to the second light-transmitting aperture is a straight line in shape; and/or on the plane where the substrate is located, an orthographic projection of an edge of the sixth section close to the second light-transmitting aperture is a straight line in shape.

11. The display panel according to claim 6, wherein
the plurality of the light-transmitting apertures in the same one of the light-transmitting aperture groups further comprise at least a second light-transmitting aperture, the first signal wire further comprises a fifth section, the second signal wire further comprises a sixth section;
on the plane where the substrate is located, an edge of an orthographic projection of the fifth section close to the second light-transmitting aperture surrounds a part of an orthographic projection of the second light-transmitting aperture, and
on the plane where the substrate is located, an edge of an orthographic projection of the sixth section close to the second light-transmitting aperture surrounds a part of the orthographic projection of the second light-transmitting aperture.

12. The display panel according to claim 11, wherein
the fifth section is convex toward a direction away from the second light-transmitting aperture; and/or the sixth section is convex toward the direction away from the second light-transmitting aperture.

13. The display panel according to claim 11, wherein
the first signal wire comprises a third section, the second signal wire comprises a fourth section;
on the plane where the substrate is located, an orthographic projection of the third section does not overlap with the orthographic projections of the plurality of the light-transmitting apertures in the same one of the light-transmitting aperture groups along the second direction, and an orthographic projection of the fourth section does not overlap with the orthographic projections of the plurality of the light-transmitting apertures in the same one of the light-transmitting aperture groups along the second direction; and
a width of the fifth section is less than a width of the third section; and/or a width of the sixth section is less than a width of the fourth section.

14. The display panel according to claim 13, wherein
on the plane where the substrate is located, an edge of the orthographic projection of the fifth section away from the second light-transmitting aperture is a straight line in shape; and/or
on the plane where the substrate is located, an edge of the orthographic projection of the sixth section away from the second light-transmitting aperture is a straight line in shape.

15. The display panel according to claim 13, wherein
the width of the fifth section is less than the width of the first section; and/or the width of the sixth section is less than the width of the second section.

16. The display panel according to claim 11, wherein
a maximum length of the first light-transmitting aperture along the second direction is W12, and a maximum length of the second light-transmitting aperture along the second direction is W22, where W12>W22; and
a distance between the first section and the second section is d12, and a distance between the fifth section and the sixth section is d22, where d12=d22.

17. The display panel according to claim 1, further comprising a light-shielding metal located between the light-shielding layer and the substrate, wherein
in a direction perpendicular to the plane where the substrate is located, the light-shielding metal does not overlap with the light-transmitting aperture.

18. The display panel according to claim 17, wherein
an angle between a side surface and a bottom surface of the light-shielding metal is P, where 92.5°≤φ≤100°.

19. The display panel according to claim 17, wherein
in a direction parallel to the plane where the substrate is located, a distance between an edge of the light-shielding metal and an edge of the light-transmitting aperture is d3, and
in the direction perpendicular to the plane where the substrate is located, a distance between the light-shielding metal and the light-shielding layer is h,
where d3≤h×tan 10°.

20. A display apparatus comprising an optical sensor and a display panel comprising a first display area, the first display area comprising a plurality of sub-pixels comprising light-emitting elements;
the display panel further comprising:
a substrate; and
a light-shielding layer located at a side of the substrate, wherein
the light-shielding layer comprises a plurality of light-transmitting aperture groups located in the first display area,
the plurality of light-transmitting aperture groups are arranged in an array along a first direction and a second direction,
the plurality of light-transmitting aperture groups each comprise N light-transmitting apertures arranged along the first direction and having areas different from each other, where N is an integer and N≥2,
in a direction perpendicular to a plane where the display panel is located, the light-transmitting apertures do not overlap with the light-emitting elements; and
an orthographic projection of the optical sensor on the plane where the substrate is located is at least partially located in the first display area.
